(19) United States
(12) Patent Application Publication
(10) Pub. No.: US 2018/0226392 A1
(43) Pub. Date: Aug. 9, 2018

(54) COMMON MODE FILTER

(71) Applicant: SAMSUNG ELECTRO-MECHANICS CO., LTD., Suwon-Si (KR)

(72) Inventors: Sang Moon LEE, Suwon-Si (KR); Sung Jin PARK, Suwon-si (KR); Hyeok Jung KWON, Suwon-si (KR); Ha Yoon SONG, Suwon-si (KR); Sung Ryong MA, Suwon-si (KR)

(21) Appl. No.: 15/793,653

(22) Filed: Oct. 25, 2017

(30) Foreign Application Priority Data
Feb. 9, 2017 (KR) 10-2017-0018265

(51) Int. Cl. H01L 27/02; H01L 23/60; H01F 17/00; H03H 7/42; H01F 27/28; H02H 9/04

(52) U.S. Cl. CPC H01L 27/0248; H01L 23/60; H01F 17/0013; H01F 2017/0066; H01F 27/28; H02H 9/04; H03H 7/427

(57) ABSTRACT

A common mode filter includes a filter portion and an electrostatic protection portion disposed on the filter portion. The electrostatic protection portion includes first and second discharge electrodes spaced apart from each other, a discharge layer disposed between the first and second discharge electrodes, and a first insulating layer cover an upper surface of the discharge layer and including flat first insulating particles and spherical second insulating particles.

### CROSS-REFERENCE TO RELATED APPLICATION(S)

This application claims the benefit of priority to Korean Patent Application No. 10-2017-0018265 filed on Feb. 9, 2017 in the Korean Intellectual Property Office, the disclosure of which is incorporated herein by reference in its entirety.

### BACKGROUND

### 1. Field

The present disclosure relates to a common mode filter.

### 2. Description of Related Art

With technological advancements, electronic devices such as mobile phones, home appliances, PCs, PDAs, LCDs, and the like, have changed from analog-type devices to digital-type devices and have tended to have increasing processing rates, due to an increase in amounts of data required to be processed. In line with this, USB 2.0, USB 3.0, and high-definition multimedia interface (HDMI) have become prevalent as high-speed signal transmission interfaces and have been used in digital devices such as personal computers and digital high-definition (HD) televisions.

Such high-speed interfaces employ a differential signal system which transmits a differential signal (differential mode signal) using a pair of signal lines, unlike single-end transmission systems which have generally been used in the art. However, high-speed digitalized electronic devices are sensitive to external stimuli, involving frequent signal distortion due to high-frequency noise.

Such an abnormal voltage and noise result from a switching voltage generated in a circuit, power noise included in a source voltage, an unnecessary electromagnetic signal, electromagnetic noise, and the like, and a common mode filter (CMF) is used to prevent an introduction of such an abnormal voltage and high-frequency noise to a circuit.

### SUMMARY

An aspect of the present disclosure may provide a structure capable of preventing occurrence of a leakage current in an insulating layer when an overvoltage such as static electricity is applied in a common mode filter including an electrostatic protection portion.

According to an aspect of the present disclosure, a common mode filter may include: a filter portion and an electrostatic protection portion disposed on the filter portion, wherein the electrostatic protection portion includes: first and second discharge electrodes disposed to be spaced apart from each other by a predetermined distance; a discharge layer disposed between the first and second discharge electrodes; and a first insulating layer disposed to cover an upper surface of the discharge layer and including flat first insulating particles and spherical second insulating particles.

According to another aspect of the present disclosure, a common mode filter may include: a filter portion and an electrostatic protection portion disposed on the filter portion, wherein the electrostatic protection portion includes: first and second discharge electrodes disposed to be spaced apart from each other by a predetermined distance; a discharge layer disposed between the first and second discharge electrodes; and an insulating layer disposed below the discharge layer and the first and second discharge electrodes and including flat first insulating particles and spherical second insulating particles.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic perspective view of a common mode filter according to an exemplary embodiment in the present disclosure;

FIG. 2 is a cross-sectional view taken along line I-I′ of FIG. 1;

FIG. 3 is a schematic enlarged cross-sectional view of portion “A” of FIG. 2;

FIGS. 4A and 4B are schematic cross-sectional views illustrating shapes of first and second insulating particles;

FIG. 5 is a scanning electron microscope (SEM) photograph of a cross-section of an electrostatic protection portion;

FIG. 6 is an enlarged photograph of portion “B” of FIG. 5;

FIG. 7 is an enlarged photograph of portion “C” of FIG. 5;

FIG. 8 is an enlarged photograph of portion “D” of FIG. 5; and

FIG. 9 is a schematic enlarged cross-sectional view of portion “A′” corresponding to portion “A” of FIG. 2 in a common mode filter according to another exemplary embodiment in the present disclosure.

### DETAILED DESCRIPTION

Exemplary embodiments in the present disclosure will now be described in detail with reference to the accompanying drawings.

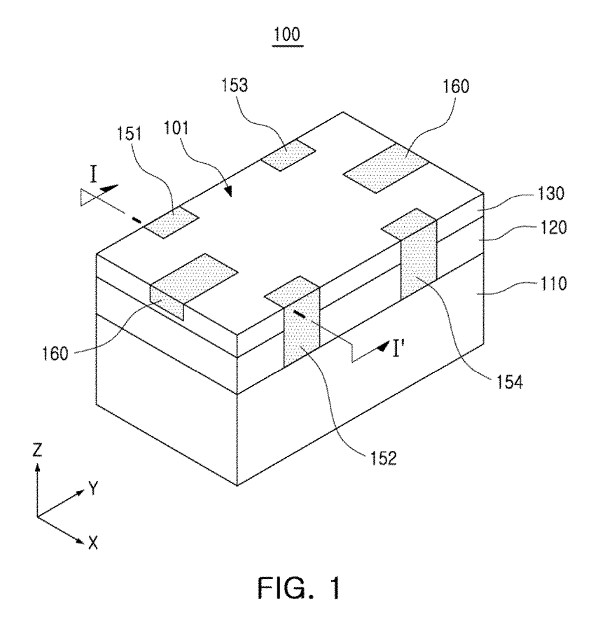

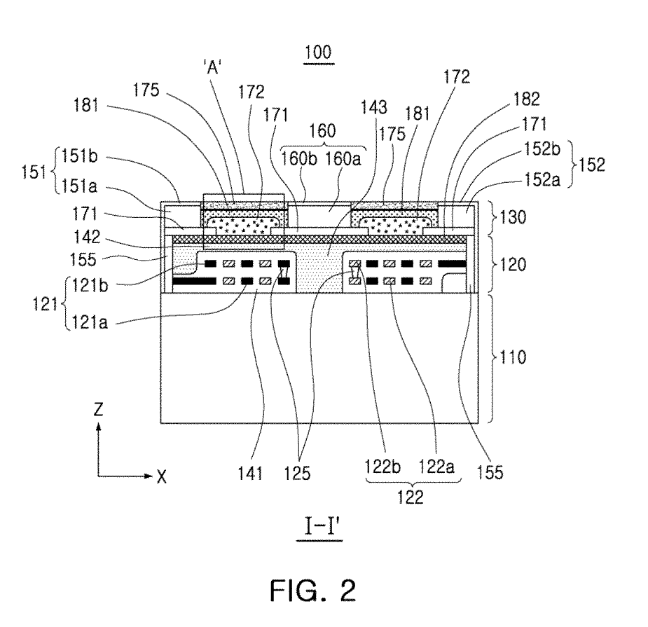

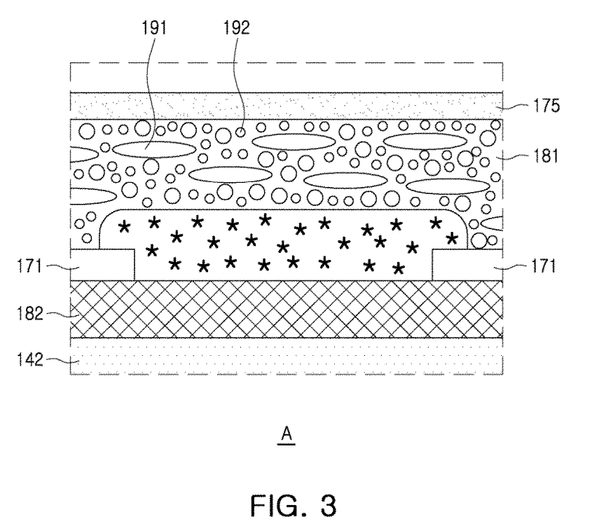

FIG. 1 is a schematic perspective view of a common mode filter according to an exemplary embodiment in the present disclosure, FIG. 2 is a cross-sectional view taken along line I-I′ of FIG. 1, and FIG. 3 is a schematic enlarged cross-sectional view of portion “A” of FIG. 2.

A structure of the common mode filter 100 according to an exemplary embodiment in the present disclosure will be described with reference to FIGS. 1 to 3.

The common mode filter 100 according to an exemplary embodiment in the present disclosure includes a body 101 and a plurality of external electrodes 151, 152, 153, and 154 and ground electrodes 160 disposed on an outer surface of the body 101.

The external electrode 151, 152, 153, and 154 may include first to fourth external electrodes 151, 152, 153, and 154, and the first to fourth external electrodes 151, 152, 153, and 154 may be disposed to be spaced apart from each other. The ground electrodes 160 may also be disposed to be spaced apart from the external electrodes 151, 152, 153, and 154.

For example, the external electrodes 151, 152, 153, and 154 may be disposed on opposing sides of the body 101 in the width direction (X direction) and the ground electrodes 160 may be disposed on opposing sides of the body 101 in the length direction (Y direction).

As illustrated in FIG. 1, the external electrodes 151, 152, 153, and 154 may be disposed on an upper surface of the body 101 but are not limited thereto and may also be disposed on a side surface of the body 101.

The external electrodes 151, 152, 153, and 154 and the ground electrodes 160 may be formed by forming metal posts 151a, 152a, and 160a, and forming plated layers 151b, 152b, and 160b on surfaces of the metal posts 151a, 152a, and 160a, but are not limited thereto. In FIGS. 1 to 3, only cross-sections of the first and second external electrodes 151 and 152 are illustrated, but the third and fourth external electrodes 153 and 154 may also have the same structure as that of the first and second external electrodes 151 and 152.

The metal posts 151a, 152a, and 160a may be formed of a metal having excellent conductivity, for example, copper, silver, gold, palladium, nickel, and the like, but are not limited thereto. The plated layers 151b, 152b, and 160b may also be formed of a metal having excellent conductivity, like the metal posts 151a, 152a, and 160a. The metal posts 151a, 152a, and 160a may be formed on discharge electrodes 171 as described hereinafter. Some of the discharge electrodes 171 may be disposed between a connection electrode 155 and the external electrodes 151, 152, 153, and 154 but are not limited thereto.

The external electrodes 151, 152, 153, and 154 are connected to coils 121 and 122 as described hereinafter to input or output a signal. The ground electrodes 160 discharge static electricity, introduced to the external electrodes 151, 152, 153, and 154. The ground electrodes 160 may also be formed on a filter portion 120, like the external electrodes 151, 152, 153, and 154. The ground electrodes 160 are usually not electrically connected to the coils 121 and 122 and, as illustrated in FIG. 1, the ground electrodes 160 may be formed between the external electrodes 151, 152, 153, and 154.

The body 101 includes a magnetic substrate 110, the filter portion 120, and an electrostatic protection portion 130.

In FIGS. 1 and 2, the electrostatic protection portion 130 is illustrated to be disposed on the filter portion 120 but is not limited thereto and the electrostatic protection portion 130 may be disposed in another portion of the body 101 under a condition in which an electrical connection relation between the electrostatic protection portion 130 and the external electrodes or the ground electrodes is the same.

The magnetic substrate 110 is positioned in a lowermost layer of the common mode filter 100 and assumes magnetism. The magnetic substrate 110 may include at least any one of a metal, a polymer, and ceramics as a material assuming magnetism. For example, the magnetic substrate 110 may be a ferrite substrate but is not limited thereto.

The filter portion 120 is disposed on the magnetic substrate 110.

The filter portion 120 includes first and second coils 121 and 122.

Both end portions of the first coil 121 may be electrically connected to the first and second external electrodes 151 and 152, and both end portions of the second coil 122 may be electrically connected to the third and fourth external electrodes 153 and 154.

The first and second coils 121 and 122 may have a shape in which a spiral electrode pattern is wound in the same direction.

Since the first and second coils 121 and 122 have a shape in which an electrode pattern is wound in the same direction, and thus, when a signal flows in the first and second coils 121 and 122, the first and second coils 121 and 122 act as resistors for a common mode signal to serve to reduce common mode noise.

The first coil 121 includes first spiral electrode patterns 121a and 121b, and the second coil 122 includes second spiral electrode patterns 122a and 122b.

The first electrode patterns 121a and 121b are disposed in spiral form and may be formed to include a metal having excellent electrical conductivity. For example, the first electrode patterns 121a and 121b may be formed of silver (Ag), palladium (Pd), aluminum (Al), nickel (Ni), titanium (Ti), gold (Au), copper (Cu), platinum (Pt), or alloys thereof. The first electrode patterns 121a and 121b may be formed using a plating method, a printing method, a photolithography method, or the like.

The second electrode patterns 122a and 122b are disposed in spiral form and may be formed to include a metal having excellent electrical conductivity. For example, the second electrode patterns 122a and 122b may be formed of silver (Ag), palladium (Pd), aluminum (Al), nickel (Ni), titanium (Ti), gold (Au), copper (Cu), platinum (Pt), or alloys thereof. The second electrode patterns 122a and 122b may be formed using a plating method, a printing method, a photolithography method, and the like.

The first electrode pattern 121a and the second electrode pattern 122a may be formed to be adjacent to each other on the same layer and may not overlap each other, but are not limited thereto. For example, the first electrode pattern 121a and the second electrode pattern 122a may be formed on different layers.

The first electrode pattern 121b and the second electrode pattern 122b may be formed to be adjacent to each other on the same layer and may not overlap each other, but are not limited thereto. For example, the first electrode pattern 121b and the second electrode pattern 122b may be formed on different layers.

The first electrode pattern 121a is wound from an outer side to an inner side, and the first electrode pattern 121b is wound from an inner side to an outer side. Inner end portions of the first electrode patterns 121a and 121b may be electrically connected by a conductive via 125.

The external electrodes 151, 152, 153, and 154 and the coils 121 and 122 may be electrically connected through the connection electrode 155 but are not limited thereto and may also be electrically connected through any other method.

The external electrodes 151, 152, 153, and 154 input a signal to the coils 121 and 122 and output a signal from the coils 121 and 122. Meanwhile, when a coil magnetic layer 142 is positioned on the filter portion 120, the external electrodes 151, 152, 153, and 154 may be formed on the coil magnetic layer 142.

The filter portion 120 may include a coil insulating layer 141. The coil insulating layer 141 may be disposed to surround the first and second coils 121 and 122. The coil insulating layer 141 may insulate the first and second coils 121 and 122 from the magnetic substrate 110, and insulate the first and second coils 121 and 122 from the coil magnetic layer 142 and a magnetic material filling a trench 143 as described hereinafter. The coil insulating layer 141 may be formed on the magnetic layer 110. As a material of the coil insulating layer 141, a polymer resin having excellent electrical insulating properties and processibility may be used. For example, an epoxy resin, a polyimide resin, and the like, may be used as a material of the coil insulating layer 141.

The coil magnetic layer 142 may be formed on the coil insulating layer 141. The coil magnetic layer 142 forms a closed-magnetic circuit along with the magnetic substrate 110. Magnetic coupling of the first and second coils 121 and 122 may be strengthened by magnetic flux intensively formed by the coil magnetic layer 142 and the magnetic substrate 110. The coil magnetic layer 142 may be a ferrite sheet.

Also, the trench 143 filled with a magnetic material may be disposed in a central portion of the coil insulating layer 141. When the trench 143, filled with a magnetic material, is included in the central portion of the coil insulating layer 141, the magnetic substrate 110, the coil magnetic layer 142, and the trench 143 form a closed-magnetic circuit.

The coil magnetic layer 142 and the trench 143 may be formed as a magnetic resin complex or a ferrite sheet including a magnetic material and a resin material. Magnetic powder allows the coil magnetic layer 142 and the trench 143 to assume magnetism and the resin material serves to enhance chargeability and dispersibility of the magnetic material in the coil magnetic layer 142 and the trench 143. Here, the magnetic powder may include ferrite. Alternatively, the coil magnetic layer 142 and the trench 143 may also be formed by stacking and compressing magnetic sheets.

An electrostatic protection portion 130 may be disposed on the filter portion 120. Here, if the electrostatic protection portion 130 is disposed in another position of the body 101, an upper cover part may be disposed on the filter portion 120.

The electrostatic protection portion 130 includes discharge electrodes 171 and a discharge layer 172 disposed between the adjacent discharge electrodes 171. The discharge electrodes 171 may be disposed to be electrically connected to at least one of the external electrodes and the ground electrodes.

The discharge layer 172 is a material having qualities of basically having high resistance which is but rapidly lowered when a surge S having a high voltage is introduced. The discharge layer 172 may be disposed between the external electrodes 151, 152, 153, and 154 and the ground electrode 160.

The discharge layer 172 may be a resin including metal particles. The metal particles may extend in one direction. According to the discharge layer 172, when a voltage is lower than a predetermined value, a current between metal particles may be insulated by the resin, but when a voltage is equal to or higher than the predetermined value, a current flows along the metal particles between the metal particles. Such a predetermined value may be a turn-on voltage (or a reference voltage).

The discharge layer 172 may be printed in a screen-printing manner. Here, after a mask including an opening to correspond to a position where the discharge layer 172 is to be formed is disposed on the external electrodes 151, 152, 153, and 154 and the ground electrode 160, the discharge layer 172 may be applied to the inside of the opening. Here, the discharge layer 172 may be present as a liquid, having fluidity. After being printed, the discharge layer 172 may be cured at high temperature.

The metal posts 151a, 152a, and 160a forming the external electrodes 151, 152, 153, and 154 and the ground electrode 160 may serve to prevent the discharge layer 172 from flowing into other part during a process of forming the discharge layer 172.

In order to maintain an appropriate shape of the discharge layer 172, insulating particles may be included in a resin. Insulating particles included in the discharge layer 172 may be inorganic insulating particles and may include spherical SiO₂ particles, for example.

An upper insulating layer 181 is disposed on the discharge electrodes 171 and the discharge layer 172 to cover the discharge electrodes 171 and the discharge layer 172. Also, a lower insulating layer 182 may be disposed below discharge electrodes 171 and the discharge layer 172. The upper and lower insulating layers 181 and 182 may be Ajinomoto build-up films (ABF) but are not limited thereto.

The upper insulating layer 181 includes a first insulating particle 191 and a second insulating particle 192. The first insulating particle 191 is flat and the second insulating particle 192 is spherical.

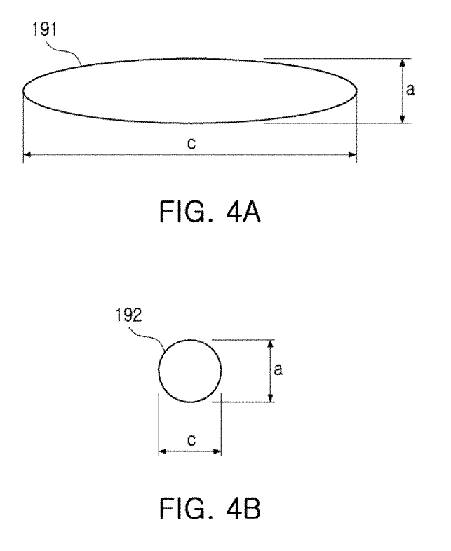

FIG. 4A is a schematic cross-sectional view illustrating a shape of the flat first insulating particles, and FIG. 4B is a schematic cross-sectional view illustrating a shape of the spherical second insulating particles.

Referring to FIGS. 4A and 4B, when a length of a shorter axis of the first and second insulating particles 191 and 192 is a and a length of a longer axis thereof is c, c/a of the first insulating particle 191 may be 2 or greater and c/a of the second insulating particle may be 1 to 1.99.

If c/a of the first insulating particle 191 is less than 2, an effect of suppressing progression of cracks as described hereinafter is lowered to increase a leakage current. Also, when c/a of the second insulating particle 192 exceeds 1.99, the upper insulating layer 181 is difficult to have an appropriate shape when formed.

A magnetic cover layer 175 is disposed on the upper insulating layer 181. The magnetic cover layer 175 may include a magnetic material and may be a ferrite sheet, for example. Since the magnetic cover layer 175 includes a magnetic material, impedance characteristics of the common mode filter 100 may be enhanced.

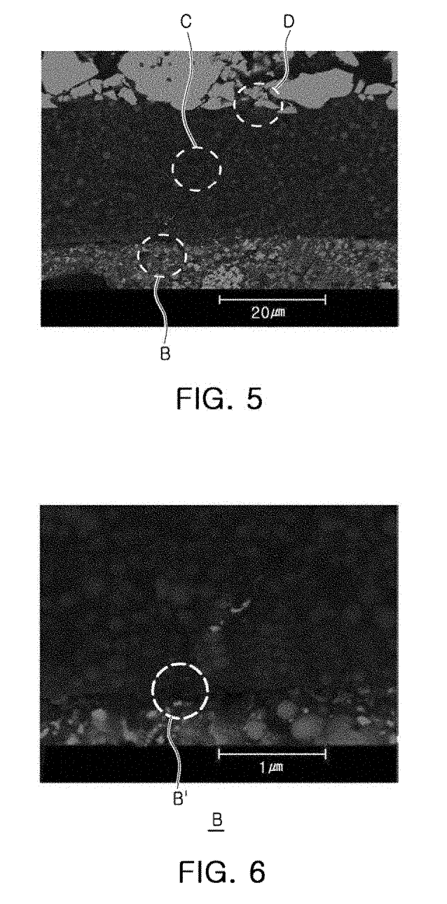

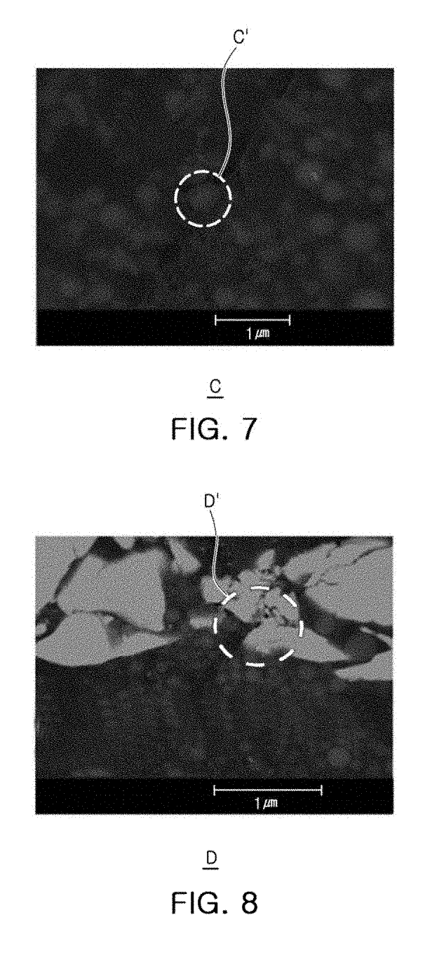

FIG. 5 is a scanning electron microscope (SEM) photograph of a cross-section of an electrostatic protection portion. FIG. 6 is an enlarged photograph of portion “B” of FIG. 5, FIG. 7 is an enlarged photograph of portion “C” of FIG. 5, and FIG. 8 is an enlarged photograph of portion “D” of FIG. 5.

In cases where static electricity having a high voltage or an overvoltage is applied to the electrostatic protection portion several times, cracks are formed in a portion of an insulating layer in which metal particles, e.g., aluminum particles, included in a discharge layer, excessively cohere, like portion B′ of FIG. 6.

Such cracks propagate along the insulating layer, like portion C′ of FIG. 7, and reach a ferrite sheet positioned on the insulating layer, like portion D′ of FIG. 8.

In the case of related art, when a high voltage (e.g., 8 kV) is applied to the electrostatic protection portion, the insulating layer and the magnetic cover layer disposed on the discharge layer are degraded and damaged. In order to prevent such a phenomenon, in the related art, a thickness of the discharge layer is reduced and a thickness of the insulating layer is increased, but durability of the electrostatic protection portion is still problematic.

Also, a magnetic material generally used as a magnetic cover layer is a ferrite sheet having a low specific resistance value of about 10⁶ Ωcm, relative to an insulating material (specific resistance value >10¹⁶ Ωcm). Thus, when dielectric breakdown in which the electrostatic protection portion is damaged by an overvoltage occurs, a leakage current flows to the magnetic cover layer through cracks.

However, in the common mode filter 100 according to an exemplary embodiment in the present disclosure, since the flat first insulating particles 191 and the spherical second insulating particles 192 are included in the upper insulating layer 181, propagation of cracks in the upper insulating layer 181 is prevented to prevent occurrence of a leakage current.

Table 1 below illustrates measurement of leakage current according to the content of the first insulating particles 191 with respect to the total content of the first and second insulating particles 191 and 192 in the upper insulating layer 181.

TABLE 1

| Content (vol %) of | Leakage | |
|---|---|---|
| first insulating particles | current (μA) | Dispersibility |
| 0 | 2.1 | ◯ |
| 10 | 1.43 | ◯ |
| 20 | 0.43 | ◯ |
| 30 | 0.67 | ◯ |
| 40 | 0.013 | ◯ |
| 50 | 0.0046 | ◯ |
| 60 | 0.0054 | ◯ |
| 70 | 0.0043 | ◯ |
| 80 | 0.0013 | ◯ |
| 90 | 0.015 | X |
| 100 | 0.079 | X |

The leakage currents illustrated in Table 1 represent average values of leakage currents measured under the application of 5V after applying a voltage of 8 kV to an electrostatic protection portion of 100 chips manufactured according to content of the first insulating particles 10 times each.

Referring to Table 1, it can be seen that the leakage current is reduced as the content of the flat first insulating particles 191 is increased. In particular, it can be seen that the leakage current is reduced to about 1/100 level when the content of the first insulating particles 191 is 40 vol % or greater, compared with a case where the content of the first insulating particles 191 is less than 40 vol %.

However, if the content of the flat first insulating particles 191 is 90 vol % or greater, dispersibility of the insulating particles of the upper insulating layer 181 is degraded to rather increase the leakage current. Here, however, an increment of the increased leakage current is relatively small, compared with the values of leakage current changed based on the content of 40 vol % as a starting point among contents of the first insulating particles 191.

The first and second insulating particles 191 and 192 may be inorganic insulating particles, i.e., SiO₂.

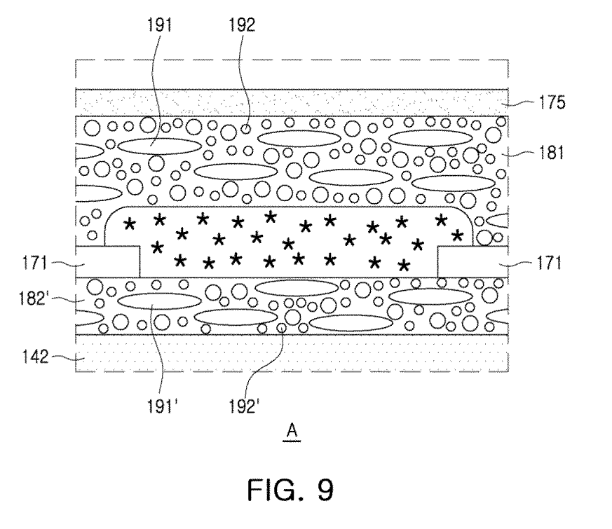

FIG. 9 is a schematic enlarged cross-sectional view of portion “A′” corresponding to portion “A” of FIG. 2 in a common mode filter according to another exemplary embodiment in the present disclosure.

Components of the common mode filter according to another exemplary embodiment in the present disclosure are the same as those of the common mode filter according to the exemplary embodiment in the present disclosure described above, except the lower insulating layer 182.

Referring to FIG. 9, in the common mode filter according to another exemplary embodiment in the present disclosure, first and second insulating particles 191′ and 192′ may be included in the lower insulating layer 182′.

The lower insulating layer 182′ is disposed to be in contact with the coil magnetic layer 142 including a ferrite sheet.

That is, the coil magnetic layer 142 is disposed between the filter portion 120 and the electrostatic protection portion 130 and is in contact with the lower insulating layer 182′, and thus, if an overvoltage is applied to the electrostatic protection portion 130 to cause cracks in the lower insulating layer 182′, a leakage current may flow to the coil magnetic layer 142 as a ferrite sheet through the cracks.

However, in the common mode filter according to another exemplary embodiment in the present disclosure, since the lower insulating layer 182′ includes the flat first insulating particles 191′ and the spherical second insulating particles 192′, propagation of cracks in the lower insulating layer 182′ may be prevented to prevent occurrence of a leakage current.

As set forth above, in the common mode filter according to an exemplary embodiment in the present disclosure, since the insulating layer disposed on the discharge electrodes and the discharge layer includes the flat first insulating particles and the spherical second insulating particles, when an overvoltage such as static electricity is applied, occurrence of a leakage current in the insulating layer may be prevented.

While exemplary embodiments have been shown and described above, it will be apparent to those skilled in the art that modifications and variations could be made without departing from the scope of the present invention as defined by the appended claims.

What is claimed is:

1. A common mode filter comprising:
a filter portion and an electrostatic protection portion disposed on the filter portion,
wherein
the electrostatic protection portion includes:
first and second discharge electrodes spaced apart from each other;
a discharge layer disposed between the first and second discharge electrodes; and
a first insulating layer covering an upper surface of the discharge layer and including flat first insulating particles and spherical second insulating particles.

2. The common mode filter of claim 1, wherein c/a of the first insulating particles is 2 or greater and c/a of the second insulating particles is 1 to 1.99, where a is a length of a shorter axis of the first and second insulating particles, and c is a length of a longer axis thereof.

3. The common mode filter of claim 1, wherein the first insulating particles are included in an amount of 40 vol % or greater with respect to a total content of the first and second insulating particles in the first insulating layer.

4. The common mode filter of claim 1, wherein the first insulating particles are included in an amount of 80 vol % or less with respect to a total content of the first and second insulating particles in the first insulating layer.

5. The common mode filter of claim 1, further comprising a magnetic cover layer disposed on the first insulating layer.

6. The common mode filter of claim 1, wherein
the filter portion further includes a coil magnetic layer disposed between the filter portion and the electrostatic protection portion, and
the electrostatic protection portion includes a second insulating layer disposed below the discharge layer and the first and second discharge electrodes and including the flat first insulating particles and the spherical second insulating particles.

7. The common mode filter of claim 1, wherein the first and second insulating particles are formed of SiO₂.

8. The common mode filter of claim 6, wherein the first insulating layer covers upper and side surfaces of the discharge layer, and the second insulating layer covers a lower surface of the discharge layer.

9. The common mode filter of claim 5, wherein the magnetic cover layer is a ferrite sheet.

10. The common mode filter of claim 6, wherein the coil magnetic layer is a ferrite sheet.

11. A common mode filter comprising:
a filter portion and an electrostatic protection portion disposed on the filter portion,
wherein
the electrostatic protection portion includes:
first and second discharge electrodes spaced apart from each other;
a discharge layer disposed between the first and second discharge electrodes; and
an insulating layer disposed below the discharge layer and the first and second discharge electrodes and including flat first insulating particles and spherical second insulating particles.

12. The common mode filter of claim 11, wherein c/a of the first insulating particles is 2 or greater and c/a of the second insulating particles is 1 to 1.99, where a is a length of a shorter axis of the first and second insulating particles, and c is a length of a longer axis thereof.

13. The common mode filter of claim 11, wherein the first insulating particles are included in an amount of 40 vol % or greater with respect to a total content of the first and second insulating particles of the insulating layer.

14. The common mode filter of claim 11, wherein the first insulating particles are included in an amount of 80 vol % or less with respect to a total content of the first and second insulating particles of the insulating layer.

15. The common mode filter of claim 11, wherein the filter portion further includes a coil magnetic layer disposed between the filter portion and the insulating layer.

16. The common mode filter of claim 11, wherein the coil magnetic layer is a ferrite sheet.
